(19) United States
(12) Patent Application Publication
(10) Pub. No.: US 2004/0125689 A1
(43) Pub. Date: Jul. 1, 2004

(54) Method and statistical micromixer for mixing at least two liquids

(76) Inventors: Wolfgang Ehrfeld, Mainz (DE); Steffen Hardt, Mainz (DE)

Correspondence Address: Hudak Shunk & Farine Company, Suite 307, 2020 Front Street, Cuyahoga Falls, OH, 44221, US

(21) Appl. No.: 10/476,813

(22) PCT Filed: May 7, 2002
(86) PCT No.: PCT/EP02/04998

(30) Foreign Application Priority Data
May 7, 2001 (DE) 101 23 093.1

(51) Int. Cl. B81B 7/00; B01F 15/00; B81B 1/00

(52) U.S. Cl. 366/165.1; 366/341

(57) ABSTRACT

The invention relates to a method for mixing at least two fluids, wherein the fluids are introduced as adjacent fluid lamellae into a swirl chamber, forming a fluid spiral flowing inward. Removal of the resulting mixture is carried out from the center of the fluid spiral. The static micromixer has a mixing chamber in the form of a swirl chamber (6), in which the inlet channels (15a, b, 16a, b) discharge in such a way that the fluid lamellae enter in the form of fluid jets forming a fluid spiral (50) flowing inward. At least one outlet (25) is fluidically connected to the swirl chamber (6) for removing the resulting mixture.

### DESCRIPTION

The invention relates to a method in accordance with claim 1 and a static micromixer for mixing at least two fluids in accordance with the preamble of claim 10.

When at least two fluids are mixed, the aim is to achieve a uniform distribution of the two fluids within a specific, usually the shortest possible, time. For this purpose it is particularly advantageous to use static micromixers as presented in the overview by W. Ehrfeld, V. Hessel, H. Löwe in Microreactors, New Technology for Modern Chemistry, Wiley-VCH 2000, pp. 41 to 85. When mixing liquids, the known static micromixers achieve mixing times ranging from 1 second to a few milliseconds by producing alternate adjacent fluid lamellae with a thickness in the μm range. Mixing gases is even substantially faster because of the higher diffusion constants. In contrast to dynamic mixers in which turbulent flow conditions predominate, static micromixers, due to the defined geometry, make it possible precisely to adjust the width of the fluid lamellae and thus the diffusion paths. The very close distribution of the mixing times that is thereby achieved in static micromixers offers a wide variety of means to optimize chemical conversions with respect to selectivity and yield. A further advantage of static micromixers is the reduction in the component size and thus the integratability in other systems, such as heat exchangers and reactors.

The interaction of two or more components coupled within such a tight space in turn results in new possibilities to optimize the process. The application potentials of micromixers extend from liquid/liquid and gas/gas mixtures to the formation of liquid/liquid emulsions, gas/liquid dispersions and thus also multiphase and phase transfer reactions. The drawbacks of these prior art micromixers are high pressure losses, which occur when the fluids to be mixed are guided through a plurality of very narrow channels, and clogging by particles, which are either carried along or are generated during a process.

The object of the invention is to provide a method and a static micromixer for mixing at least two fluids, which causes less pressure loss and at the same time enables very rapid and uniform mixing in a small overall volume.

According to the invention, this object is attained by a method set forth in claim 1 and a static micromixer set forth in claim 10.

The term fluid as used hereinafter is defined as a gaseous or liquid substance or a mixture of such substances, which may contain one or more dissolved or dispersed solid, liquid or gaseous substances.

The term mixing also comprises the processes of dissolving, dispersing and emulsifying. Accordingly, the term mixture includes solutions, liquid/liquid emulsions, gas/liquid dispersions and solid/liquid dispersions.

Alternate adjacent fluid lamellae or inlet channels in the case of two fluids A, B means that these lamellae or channels lie side by side and alternate in at least one plane, resulting in an ABAB sequence. The term “alternate adjacent” in the case of three fluids A, B, C includes different sequences, such as ABCABC or ABACABAC. The fluid lamellae or inlet channels can also lie alternately adjacent in more than one plane, e.g. offset in two dimensions in the manner of a chessboard.

The method according to the invention for mixing at least two fluids includes at least two process steps. In the first step, the two fluids are introduced into a swirl chamber as adjacent fluid lamellae forming an inwardly flowing fluid spiral. In the second process step, the resulting mixture is removed from the center of the fluid spiral.

This adjacent introduction of the fluid lamellae into the swirl chamber means that the fluid lamellae are introduced directly next to one another or spaced at a distance from one another.

Only the fluid lamella flowing in the outermost turn adjoins the lateral inner surfaces of the swirl chamber. The inner turns of the fluid spiral on their two sides adjoin the fluid lamellae of the preceding and the subsequent turn flowing in the same direction. As a result, essentially only the contact with the upper and lower inner surface of the swirl chamber contributes to the friction. The pressure loss obtained with this mixer is therefore lower than the pressure loss in a mixer with a correspondingly long mixing path in which the fluids flow alternately adjacent to one another in the form of fluid lamellae. Furthermore, a compact construction is afforded by the spiral-shaped course while providing a long mixing path and thus a longer retention time.

A further advantage is the contact of a turn of the fluid spiral with the preceding and the subsequent turn, which contributes to the diffusive intermixing of the fluid lamellae.

Laminar flow conditions advantageously prevail in the interior of the swirl chamber. It is also feasible, however, to have turbulent flow conditions in partial areas in an overall inwardly flowing spiral fluid stream.

To obtain complete mixing by diffusion, the inwardly flowing spiral fluid stream has a sufficient length and thus a sufficient number of turns to achieve a sufficient retention time for each fluid volume flowing into the swirl chamber.

The fluid lamellae when introduced into the swirl chamber preferably have a width ranging from 1 μm to 1 mm and a depth ranging from 10 μm to 10 mm, particularly preferably a width of 5 μm to 50 μm and a depth ranging from 50 pm to 5 mm.

The tapering of the fluid lamellae toward the center of the fluid spiral supports the rapid mixing of the fluids.

Furthermore, the fluid lamella flowing in the outermost turn along the lateral inner surfaces of the swirl chamber prevents substances from being deposited on the lateral inner surfaces of the swirl chamber.

Advantageously, the fluids are separately introduced into the swirl chamber as individual fluid lamellae in one plane. Especially advantageously, this is realized by introducing the fluids into the swirl chamber separately from one another through inlet channels distributed around the swirl chamber, preferably inlet channels that are equidistantly distributed around the swirl camber. The fluid streams to be introduced can contain either the same fluids or different fluids that are only contacted and mixed in the common space.

According to a further embodiment, the fluids can be separately introduced into the swirl chamber as individual fluid lamellae in several planes. It is possible, for example, to introduce one or more alternate adjacent gas lamellae and liquid lamellae into the swirl chamber in a first plane and additional liquid lamellae in subsequent planes. It is also possible to introduce fluid lamellae only in the uppermost plane and no liquid lamellae in all the subjacent planes. This can be realized, for example, by increasing the height of the swirl chamber. The outlet is located, for example, on the floor and the inlets near the ceiling of the swirl chamber such that a vertical motion is superimposed on the planar motion of the fluid. Instead of spiral trajectories, helical trajectories are obtained. This makes it possible, for example, to increase the retention time and contact time of gas bubbles in or with a liquid phase. If additional total fluid streams are introduced into the swirl chamber in the subjacent planes, these streams form fewer turns before they are removed from the swirl chamber.

By lengthening the fluid stream and increasing the number of turns of the fluid spiral to be formed, this embodiment further increases the retention time of the fluid streams in the swirl chamber.

Advantageously, at least one fluid is introduced into the swirl chamber as at least two fluid lamellae.

According to a preferred embodiment, at least two fluids, respectively, are spatially alternately introduced into the swirl chamber as at least two fluid lamellae, such that alternate adjacent fluid lamellae of the two fluids form in the fluid spiral. As a result, two or more fluid lamellae are obtained which form inwardly flowing fluid spirals. The fluid spirals lie in a common plane and around a center such that the corresponding turns are adjacent to one another. If, for example, two or three fluid lamellae are introduced, a kind of double or triple spiral results.

Advantageously, the swirl chamber has a substantially round or oval shape in one or more planes of the fluid spiral to enable the formation of the fluid spiral in the presence of laminar flow conditions and to reduce the pressure loss.

It may be advantageous to introduce an additional fluid into the fluids and/or into the swirl chamber. This additional fluid can contain an agent to stabilize the mixture, e.g. an emulsifier. It is also feasible for the fluids to have such an agent already mixed into them.

Advantageously, the fluids are focused-before they are introduced into the swirl chamber. Focusing in this context should be understood as a compression of the fluid that results in an increase of the flow rate. This can be produced by a constriction prior to the entry into the swirl chamber such that the thickness of the fluid lamellae is reduced. The cross-sectional constriction can be more than 40%, preferably more than 50%, particularly more than 60%. The thinner the fluid lamellae the more turns are formed in the fluid spiral inside the swirl chamber.

The desired conditions can be adjusted, in particular, by correspondingly selecting the cross-sectional area of the fluid lamellae introduced into the swirl chamber, the shape and dimensions of the swirl chamber and the cross-sectional area of the outlet for removing the resulting mixture from the swirl chamber.

Advantageously, the fluid lamellae are introduced into the swirl chamber at an acute angle or preferably tangentially, particularly to generate as many turns of the fluid spiral as possible and to prevent dead water zones, i.e. areas through which there is no continuous flow.

The static micromixer is characterized in that the mixing chamber is a swirl chamber into which the fluid channels discharge in such a way that the fluid lamellae enter as fluid jets while forming an inwardly flowing fluid spiral and that at least one outlet fluidically communicates with the swirl chamber for the removal of the resulting mixture.

With respect to the advantages connected with this micromixer, reference is made to the above descriptions regarding the method according to the invention, particularly the low pressure loss, the increased contact areas available for diffusive mixing and the small structural shape.

Rapid mixing is achieved by producing very thin fluid lamellae and thereby shortening the diffusion path. These fluid lamellae are introduced into the swirl chamber, which further shortens the diffusion path by tipping the fluid lamellae and by reducing the lamellar width. The swirl chamber can be configured on a relatively large scale (large diameter, great height), but the fluid lamellae produced are nevertheless very thin. The pressure loss in the swirl chamber can be kept low because of the large hydraulic diameter. As a result, only the constriction of the inlet channels substantially contributes to the pressure loss. This constriction, however, can be very localized, so that the pressure loss is only moderate.

The minimum obtainable lamellar thickness of the mixer is essentially defined by the width of the inlet channels to the swirl chamber. For production reasons, however, this width cannot be selected arbitrarily small. The advantage of the mixer is its small space requirement and its simple production.

It is particularly preferred if the inlet channels are arranged to discharge in one plane around the common swirl chamber. The at least two inlet channels are spatially separate from one another, preferably distributed equidistantly around the swirl chamber and fluidically communicating only through the common swirl chamber. These structures can be used to introduce the same fluids, e.g. twice the fluids A, B, or different fluids, e.g. the fluids A, B and C, D. It is also possible, however, to arrange at least two inlet channels for introducing the fluids in different planes around the swirl chamber.

For a simple technical implementation it is advantageous if the inlet channels and/or the swirl chamber have the same depth.

Particularly preferably, the swirl chamber is substantially cylindrical in shape. Advantageously, the height of the inlet channels, at least in the area of their discharge, is smaller or equal to the height of the swirl chamber. The inlet channels are preferably provided only in an upper area of the swirl chamber, so that their height is smaller than the height of the swirl chamber. In this embodiment, the area of the swirl chamber between the inlet channels and the floor does not have any inlet channels.

According to one variant of the embodiment, the inlet channels have a substantially constant cross section over their entire length.

According to another variant of the embodiment, the inlet channels have a cross section tapering toward the swirl chamber, e.g. a funnel-shaped or tear drop-shaped cross section. Since this constriction occurs only directly at the junction to the swirl chamber, the pressure loss is limited. In addition to tear drop-shaped channels, however, other embodiments of this type, e.g. feeds from above, are also feasible. The acceleration of the flow is not important here, only the fact that the constriction produces a small lamellar thickness. This reduces the width and/or the cross-sectional area of the fluid lamellae entering into the swirl chamber while simultaneously increasing the flow rate.

The ratio of the width of the inlet channels discharging into the swirl chamber to the diameter of the swirl chamber in the one or more planes of the forming fluid spiral is advantageously less than or equal to 1:10. The swirl chamber has preferably a round or oval cross section in the one or more planes.

The diameter of the swirl chamber is preferably 2 mm to 20 cm, especially preferably 5 mm to 10 cm.

The one or more outlet channels preferably discharges into the swirl chamber underneath and/or above a central area, particularly in area of the center point. Compared to the diameter of the swirl chamber and the cross-sectional area of the incoming inlet channels, the cross-sectional area of the one or more outlets is preferably dimensioned in such a way that a fluid spiral with a plurality of turns can form. The ratio of the diameter of the outlet to the diameter of the swirl chamber is preferably less than 1:5.

According to a further embodiment, one or more additional inlet channels for feeding an additional fluid discharges into at least one inlet channel or into the swirl chamber. Such fluids may contain an agent to stabilize the mixture, e.g. an emulsifier. These additional inlet channels advantageously discharge tangentially into the swirl chamber, such that a stream of the additional fluid lies between adjacent turns of the fluid spiral.

In a preferred embodiment, the inlet channels are preferably arranged in such a way that they discharge into the swirl chamber at an acute angle or preferably tangentially. This makes it possible, in particular, to introduce the fluids as fluid lamellae while maintaining laminar flow conditions and to form a fluid spiral with a plurality of turns.

According to another preferred embodiment, the fluid guide structures, such as inlet channels, swirl chambers or inlets, are recesses and/or openings formed in plates made of a material that is sufficiently inert to the fluids to be mixed. Recesses, such as grooves or blind holes are surrounded by this material in one plane and perpendicularly thereto. Openings, such as slits or holes, on the other hand, go through the material, i.e. the material surrounds them laterally only in one plane. The open structures of the recesses and openings are formed into fluid guide structures, such as inlet channels, swirl chambers or inlets when the plates are stacked on top of one another. The final cover plate and/or bottom plate, which make the plate stack of fluid-tight toward the outside, are provided with inlets for the two fluids and/or at least one outlet for the resulting mixture. The inlets and/or outlets in the cover plate and/or the bottom plate may be grooves and/or openings.

In a preferred variant of this embodiment, the structures of the inlet channels and the swirl chamber are made as recesses and/or openings in at least one plate, which is used as a mixing plate. A distributor plate and/or bottom plate connected with the mixing plate seals these open structures fluid-tight. A cover plate in turn seals the inlets of the distributor plate.

The cover plate and/or the bottom plate, respectively, have inlets for the two fluids and at least one outlet for the resulting mixture.

According to a further variant of this preferred embodiment, the static micromixer has a perforated plate between the mixing plate and the distributor plate, with which it is connected fluid-tight, for a separate introduction of the fluids from the inlets in the distributor plate to the inlet channels of the mixing plate. For this purpose, the perforated plate advantageously has a series of openings in the form of holes for each fluid to be introduced. Each hole is associated with precisely one inlet channel.

Thus, in the case of two fluids, the openings each serve alternately to introduce the first fluid or the second fluid.

Depending on the fluids used, suitable materials are, for example, polymer materials, metals, alloys, e.g. high-grade steels, glasses, quartz glass, ceramics or semiconductor materials, such as silicon. The plates are preferably 10 μm to 5 mm, especially 50 um to 1 mm thick. Suitable methods for interconnecting the plates so that they are fluid tight are, for example, pressing, the use of seals, gluing or anodic bonding.

Methods for structuring the plates are the known precision-mechanical or micromechanical production processes, such as laser ablation, spark erosion, injection molding, embossing or galvanic deposition. Also suitable are LIGA processes, which include at least the steps of structuring with high-energy radiation and galvanic deposition and possibly shaping.

The method according to the invention and the static micromixer are advantageously used to carry out chemical reactions with two or more substances, both of which are contained in an introduced fluid or a first substance is contained in a first fluid and a second substance in an additional introduced fluid. For this purpose, means for controlling the chemical conversion are advantageously integrated into the static micromixer, e.g. temperature or pressure sensors, flow meters, heating elements, retention pipes or heat exchangers. In a static micromixer, these means can be disposed on a plate above and/or below the plate with the swirl chamber and can be functionally communicating with that plate. To carry out heterogeneously catalyzed chemical conversions, the static micromixer can also have a catalytic material.

It is particularly advantageous to use the method according to the invention and the micromixer according to the invention to produce a gas/liquid dispersion. At least one introduced fluid contains a gas or a gas mixture and at least one additional introduced fluid contains a liquid, a liquid mixture, a solution, a dispersion or an emulsion.

The invention will now be described in greater detail, by way of example, with reference to exemplary embodiments of the static micromixer according to the invention depicted in the drawings, in which:

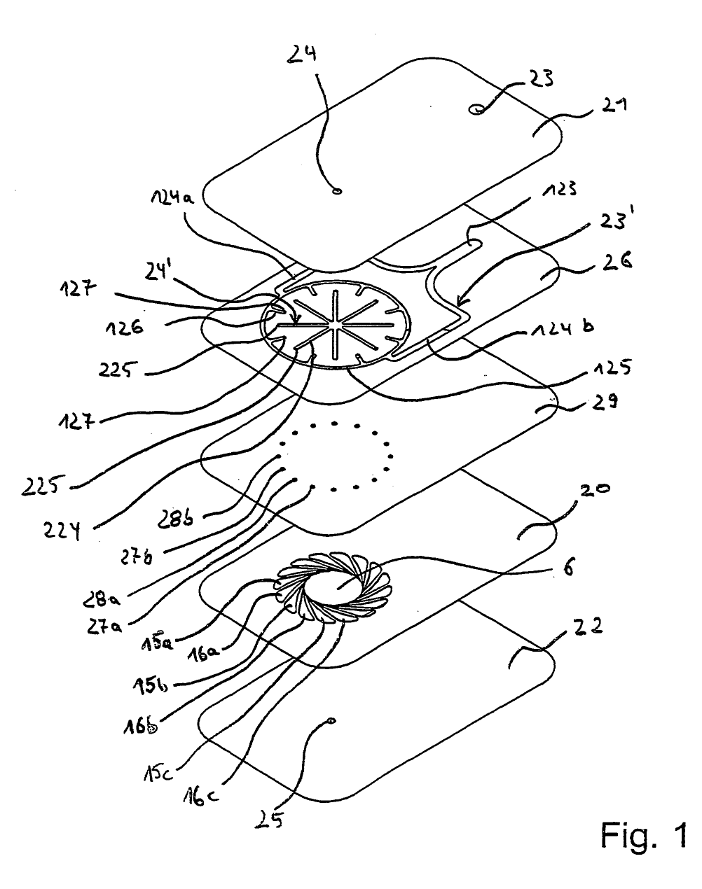

FIG. 1 is a perspective view of a static micromixer consisting of a cover plate, a distributor plate, a perforated plate, a mixing plate and a bottom plate, which are shown separately from one another.

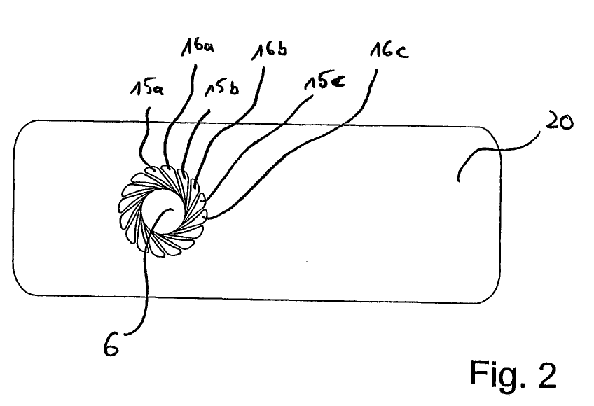

FIG. 2 is a top view of a preferred mixing plate according to FIG. 1,

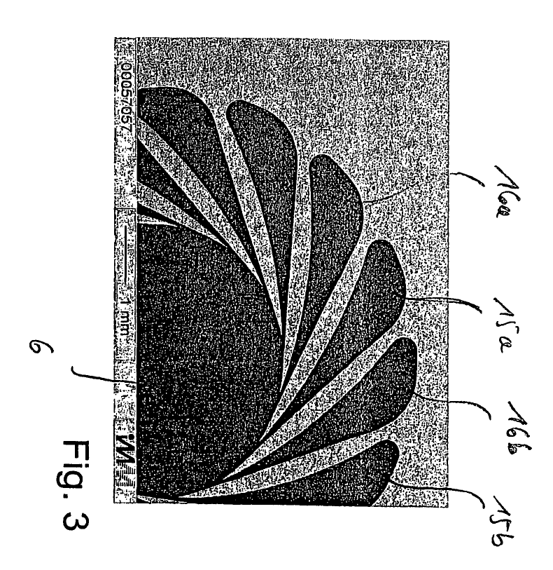

FIG. 3 is an SEM photograph of a detail of a mixing plate with a swirl chamber and inlet channels,

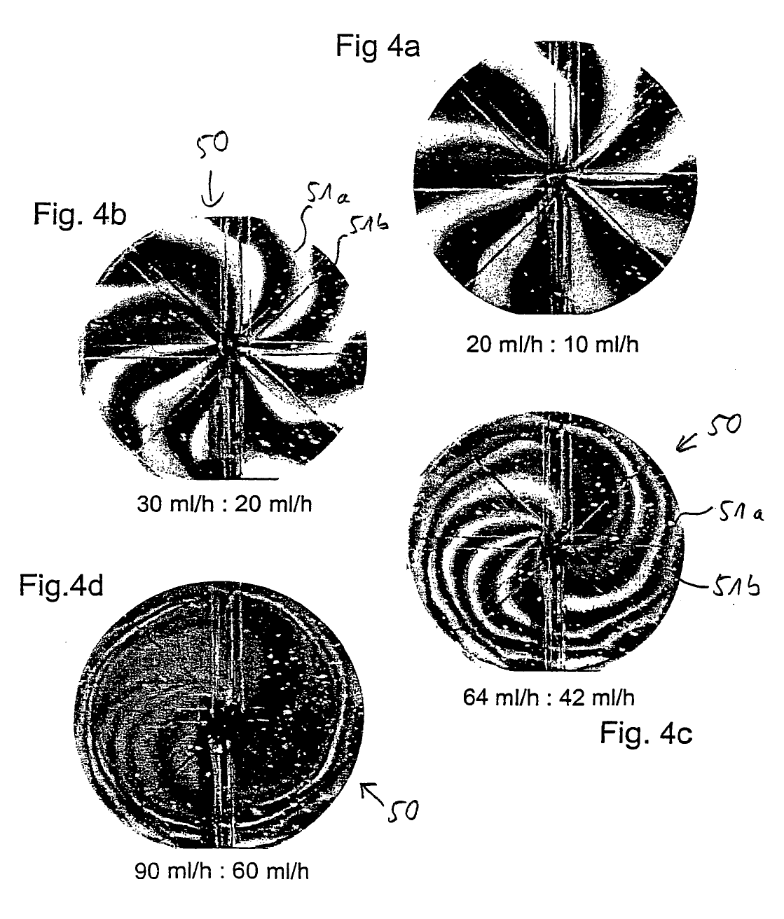

FIGS. 4a, b, c, d are photographs of details of the micromixer when differently colored aqueous solutions are mixed at different flow rates,

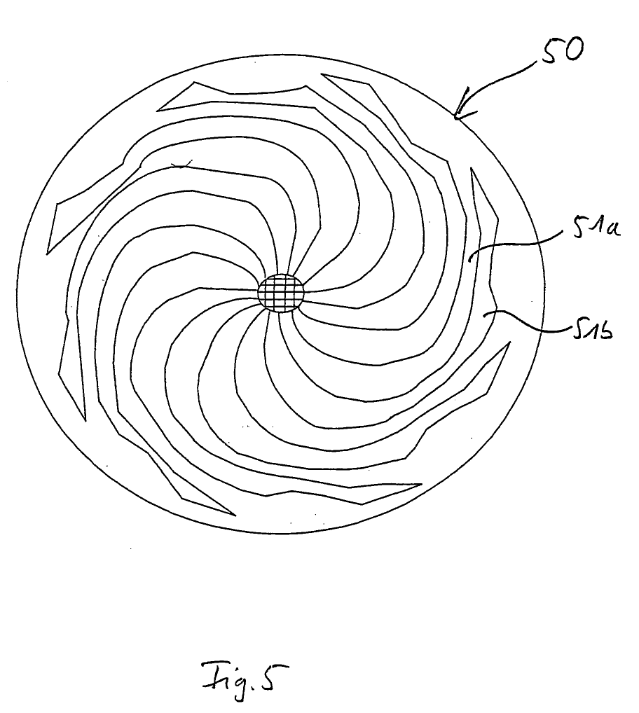

FIG. 5 is a graphic rendering of FIG. 4c, and

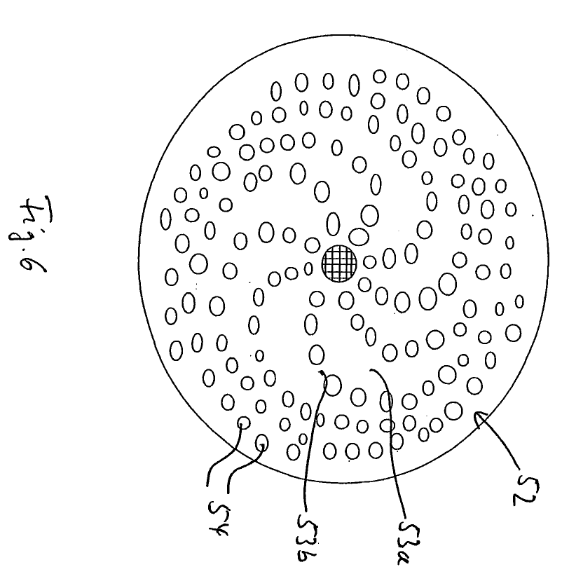

FIG. 6 shows a fluid spiral for producing a gas/liquid mixture.

FIG. 1 is a perspective view of a static micromixer 1 with a cover plate 21, a distributor plate 26, a perforated plate 29, a mixing plate 20 and a bottom plate 22, which are shown separately from one another.

The cover plate 21 has, respectively, an inlet 23 for the fluid A and an inlet 24 for the fluid B in the form of a through bore. The bores are arranged in such a way that when the plates 21, 26, 29, 20, 22 are stacked on top of one another the inlets 23, 24 fluidically communicate with groove-like inlets 23′, 24′ arranged on the distributor plate 26. The groove-like inlets 23′, 24′ form a channel system for distributing the two fluids among the bores 27a, 27b, . . . and 28a, 28b . . . of the perforated plate 29. The inlet 23′ has a channel 123 that forks into channel branches 124a, 124b, which in turn discharge into the annular channel 125 on both sides. The annular channel 125 has radial spokes 126, at the end points of which bores 127 are arranged.

The groove-like inlet 24′ has radial channel sections 224 that are arranged in a star shape and have bores 225 at their outer end points.

The groove-like inlets 23′, 24′ are provided with through bores at their end points in such a way that on the subjacent perforated plate 29 the fluid A and the fluid B can be alternately guided to circularly arranged through bores 27a, 27b, . . . and 28a, 28b . . . , without any significant pressure loss.

The mixing plate 20 shown in a top view in FIG. 2 has inlet channels 15a, 15b, . . . for fluid A and inlet channels 16a, 16b, . . . for fluid B and a swirl chamber 6. The inlet channels 15a, b . . . and 16a, b . . . are arranged equidistantly around the swirl chamber 6 and discharge tangentially into the swirl chamber. As seen from the top, each inlet channel has a curved tear-drop shape with a cross section tapering in the direction of the swirl chamber. The bottom plate shown in FIG. 1 has an outlet 25 in the form of a through bore, which—when the plates are stacked on top of one another—is positioned such that it is fluidically connected with a central area of the mixing plate 20. The bores 27a, 27b, . . . and 28a, 28b, . . . of the perforated plate 29 are likewise arranged in a circle such that the inlet channels 15a, 15b, . . . and 16a, 16b, . . . are each in fluidic contact with a bore. The inlet channels 15a, 15b and 16a, 16b . . . each discharge tangentially into the swirl chamber 6, which is formed by a circular chamber in the plane of the mixing plate 20. The structures of the inlet channels 15a, 15b, . . . and 16a, 16b . . . and the structures of the swirl chamber 6 are formed as openings that go through the material of the mixing plate 20, so that these structures have the same depth. The subjacent bottom plate 22 and the superjacent perforated plate 29 cover these structures, which are open to two sides, so that channels or chambers are formed.

When the micromixer 1 is ready for operation, the plates 21, 26, 29, 20 and 22 depicted separately here are stacked on top of one another and are fluidically interconnected so as to form a seal, such that the open structures, e.g. grooves and bores or openings, are covered to form channels and chambers. The stack of plates 21, 26, 29, 20 and 22 thus obtained can be accommodated in a mixer housing that is equipped with suitable fluidic connections for introducing two fluids and for removing the resulting fluid mixture. In addition, the housing can apply a closing force to the stack of plates for a fluid-tight connection. It is also feasible to operate the stack of plates as a micromixer 1 without a housing. For this purpose, fluidic connections, e.g. hose couplings, are advantageously connected with the inlets 23, 24 and the outlet 25 of the cover plate 21 and the bottom plate 22.

During the actual mixing process, a fluid A and a fluid B each is introduced into the inlet bore 23 and the inlet bore 24 of the cover plate 21. These fluids each flow through the inlets 23′ and 24′ of the distributor plate 26 and from there are each uniformly distributed into the bores 27a, 27b, . . . and 28a, 28b, . . . of the perforated plate 29. From the bores 28a, 28b, . . . of the perforated plate 29, the fluid A flows into the inlet channels 15a, 15b, of the mixing plate 20, which are arranged precisely subjacent thereto. Likewise, the fluid B flows from the bores 27a, 27b, . . . of the perforated plate 29 into the precisely subjacent inlet channels 16a, 16b . . . . The fluid streams A, B guided separately in the inlet channels 15a, 15b, . . . and 16a, 16b . . . , are combined in the swirl chamber 6 while forming alternate adjacent fluid lamellae with the sequence ABAB. Due to the tapering shape of the inlet channels 15a, 15b, . . . and 16a, 16b, . . . the fluid lamellae are focused and introduced tangentially into the swirl chamber 6. Inside the swirl chamber 6 a concentric inwardly flowing fluid spiral forms. The resulting mixture of the fluids A, B is discharged through the outlet bore 25 of the bottom plate 22 which is located over the center point of the swirl chamber 6.

The REM photograph of a detail of a mixing plate 20 of a mixer according to the invention reproduced in FIG. 3 shows a swirl chamber 6 and the inlet channels 15a, 15b, . . . and 16a, 16b, . . . which appear as dark gray areas in this top view. In this plate, the tapering inlet channels discharge approximately tangentially into the swirl chamber.

### EXAMPLE

In flow visualization tests of the mixing of liquids shown in the photographs of the swirl chamber depicted in FIGS. 4a, 4b, 4c, and 4d, clear water and water dyed blue were introduced tangentially into a swirl chamber. At low flow rates, as shown in FIG. 4a, the liquids flow almost directly to the outlet center without forming a fluid spiral. With increasing flow rates, as shown in FIGS. 4b to 4d, fluid spirals 50 form. With increasing speed, the length of the spiral turns 51a, b or the lamellae and thus the retention time of the liquid in the micromixer increase. At the same time, the lamellae become thinner, which accelerates the mixing. The four flow patterns depicted in FIGS. 4a to 4d, however, all correspond to test parameters whose retention time is still too short to produce complete mixing.

FIG. 5 shows a graphical representation of the photograph of FIG. 4c.

The results of the gas/liquid contacting also show spiral flow patterns. FIG. 6 shows such a fluid spiral 52 consisting of fluid turns 53a and gas turns 53b that are formed by gas bubbles 54. This pattern, however —in contrast to the contacting of liquids—is not the only one that was found over a wide range of flow rates. Other patterns were also observed, e.g., an irregular injection of gas into the liquid at low gas flows and a broad central gas core surrounded by a thin ring of liquid at high gas flows. Here, the formation of the spiral and thus the large surface necessary for gas/liquid contacting requires careful adjustment of the flows of gas and liquid.

Initial preliminary tests for the absorption of oxygen in water at room temperature show that the micromixer according to the invention is more powerful than T-pieces and other micromixers and is even comparable to microbubble columns. Microbubble columns as described in the publication by V. Hessel, W. Ehrfeld, K. Golbig, V. Haverkamp, H. Löwe, M. Storz, Ch. Wille, A. Guber, K. Jähnisch, M. Baerns entitled “Gas/Liquid Microreactors for Direct Fluorination of Aromatic Compounds Using Elemental Fluids” in Microreaction Technology: Industrial Prospects, IMRET 3: Proceedings of the Third International Conference on Microreaction Technology, ed.: W. Ehrfeld, Springer-Verlag, Berlin (2000) pp. 526-540, are complex special tools for gas/liquid contacting with high specific phase interfaces. At a flow rate of 10 ml/h of oxygen and 1000 ml/h of water, the absorption of the oxygen used was found to be 39% at room temperature in the micromixer according to the invention, corresponding to an oxygen concentration of 13.3 mg/l. Under otherwise identical test conditions, microbubble columns with channels having a cross section of 300 μm x 300 μm achieved 46% effectiveness and 42% with channels having a cross section of 50 μm x 50 μm. The oxygen absorption in interdigital micromixers as discussed in the overview by W. Ehrfeld, V. Hessel, H. Löwe in Microreactors, New Technology for Modern Chemistry, Wiley-VCH 2000, pp. 64 to 73 is only 30%.

TABLE 1

| | Absorption Efficiency | Concentration |
|---|---|---|
| Mixer Type | [%] | [g/l] |
| Micromixer according | 39 | 5.2 |
| to the invention | | |
| Interdigital micromixer | 30 | 4.0 |
| Microbubble column | 46 | 6.1 |
| (300 μm × 300 μm) | | |
| Microbubble column | 42 | 5.2 |
| (50 μm × 50 μm) | | |

The efficiency of the micromixer according to the invention in the absorption of oxygen in water or with respect to the concentration of oxygen in water is approximately comparable to that of the microbubble column. The pressure loss that accompanies mixing, however, is substantially lower in the micromixer according to the invention than in the microbubble column. This is true because only the fluid lamella flowing in the outermost turn adjoins the lateral inner surfaces of the swirl chamber, while both sides of the inner turns of the fluid spiral adjoin the fluid lamellae of the preceding and the subsequent turn which flow in the same direction.

As a result, essentially only the contact with the upper and the lower inner surface of the swirl chamber contributes to the friction. In contrast thereto, the microbubble columns require long narrow channels, which result in high pressure loss. Furthermore, the spiral course in the micromixer according to the invention affords a compact construction with a long retention path and a long retention time.

### List of Reference Numerals

1 static micromixer

6 swirl chamber

15a, 15b inlet channels for fluid A

16a, 16b inlet channels for fluid B

17a, 17b inlet channels for an additional fluid

20, 20′, 20″, 20′″ mixing plate

21 cover plate

22 bottom plate

23, 23′, 23″, 23′″ inlet for fluid A

24, 24′, 24″, 24′″ inlet for fluid B

25 outlet

26 distributor plate

27a, 27b bore for fluid A

28a, 28b bore for fluid B

29 perforated plate

40 total system

41 gas/gas mixer

42 retention pipe

43, 43″, 43′″ opening

50 fluid spiral

51a, b turn

52 fluid spiral

53a, b turn

54 gas bubble

123 channel

124a, 124b channel branch

125 annular channel

126 radial channel section

127 bore

224 radial channel section

225 bore

1. Method for mixing at least two fluids comprising the following steps:
Introducing the fluids as adjacent fluid lamellae into a swirl chamber while forming an inwardly flowing fluid spiral,
Discharging the resulting mixture from the center of the fluid spiral.

2. Method as claimed in claim 1, characterized in that the fluids are each introduced separately into the swirl chamber as individual fluid lamellae in one plane.

3. Method as claimed in claim 1, characterized in that the fluids are each introduced separately into the swirl chamber as individual fluid lamellae in a plurality of planes.

4. Method as claimed in any one of the preceding claims, characterized in that the at least one fluid is introduced into the swirl chamber as at least two fluid lamellae.

5. Method as claimed in any one of the preceding claims, characterized in that at least two fluids, respectively, are introduced into the swirl chamber as at least two fluid lamellae spatially alternating such that alternate adjacent fluid lamellae of the two fluids are formed in the fluid spiral.

6. Method as claimed in any one of the preceding claims, characterized in that the swirl chamber in the one or more planes of the fluid spirals being formed has a substantially round or oval shape.

7. Method as claimed in any one of the preceding claims, characterized in that an additional fluid, e.g. an additional fluid containing an agent that stabilizes the mixture, is introduced into the fluids or into the swirl chamber.

8. Method as claimed in any one of the preceding claims, characterized in that the fluids are focused prior to being introduced into the swirl chamber.

9. Method as claimed in any one of the preceding claims, characterized in that the fluids are introduced into the swirl chamber as fluid lamellae at an acute angle or preferably tangentially.

10. Static micromixer for mixing at least two fluids having at least two inlet channels for separately introducing the fluids as fluid lamellae and having a mixing chamber into which the inlet channels discharge,
characterized in that
the mixing chamber is a swirl chamber (6) into which the inlet channels (15a, b, 16a, b) discharge such that the fluid lamellae enter as fluid jets while forming an inwardly flowing fluid spiral (50), and at least one outlet (25) is fluidically connected with the swirl chamber (6) for removing the resulting mixture.

11. Static micromixer as claimed in claim 10, characterized in that at least two inlet channels (15a, 15b, . . . ) and/or (16a, 16b, . . . ) arranged around the swirl chamber (6) in one plane are provided for introducing the fluids.

12. Static micromixer as claimed in claim 10 to 11, characterized in that the inlet channels (15a, 15b, . . . ) and (16a, 16b, . . . ) and/or the swirl chamber (6) have the same depth.

13. Static micromixer as claimed in claim 10, characterized in that at least two inlet channels (15a, 15b, . . . ) and/or (16a, 16b, . . . ) arranged around the swirl chamber (6) in different planes are provided for introducing the fluids.

14. Static micromixer as claimed in any one of claims 10 to 13, characterized in that the swirl chamber (6) has a substantially round or oval cross section in one or more planes.

15. Static micromixer as claimed in any one of claims 10 to 14, characterized in that the swirl chamber (6) has a substantially cylindrical form.

16. Static micromixer as claimed in any one of claims 10 to 15, characterized in that the inlet channels (15a, 15b, . . . ) and/or (16a, 16b, . . . ) have a cross section tapering in the direction of the swirl chamber (6).

17. Static micromixer as claimed in any one of claims 10 to 16, characterized in that one or more outlets (25) discharge below and/or above a central area of the swirl chamber (6).

18. Static micromixer as claimed in any one of claims 10 to 17, characterized in that one or more inlet channels for introducing an additional fluid, e.g. a fluid containing an agent that stabilizes the mixture, discharge into the inlet channels (15a, 15b, . . . ) and/or (16a, 16b, . . . ) or into the swirl chamber (6).

19. Static micromixer as claimed in any one of claims 10 to 18, characterized in that the inlet channels (15a, 15b, . . . ) and/or (16a, 16b, . . . ) discharge into the swirl chamber (6) at an acute angle or preferably tangentially.

20. Static micromixer as claimed in any one of claims 10 to 19, characterized in that the fluid guide structures, such as the inlet channels (15a, 15b, . . . ) and (16a, 16b, . . . ), the swirl chamber (6) and the inlets (23, 23′, 24, 24′) are recesses and/or openings formed in plates (26, 29, 20) which are made of a material that is sufficiently inert to the fluids to be mixed, and these open structures are sealed by stacking these plates (26, 29, 20) and by at least one cover plate and/or bottom plate (21, 22) connected with the plate stack to form a fluid-tight seal, wherein the cover plate (21) and/or the bottom plate (22) have at least one inlet (23, 24) for the two fluids and/or at least one outlet (25) for the resulting mixture.

21. Static micromixer as claimed in claim 20, characterized by a perforated plate (29), which is arranged between a mixing plate (20) having inlet channels (15a, 15b, . . . ) and (16a, 16b, . . . ) as well as a swirl chamber (6) and a distributor plate (26) and is connected therewith so as to be fluid-tight for separately introducing the fluids from the at least one inlet (23′, 24′) in the distributor plate (26) via holes (27a, 27b, . . . , 28a, 28b) provided in the perforated plate (29) into the inlet channels (15a, 15b, . . . ) and/or (16a, 16b, . . . ) in the mixing plate (20).

22. Use of the method and/or the static micromixer as claimed in any one or more of the preceding claims for reacting at least two substances, wherein both substances are contained in an introduced fluid or a first substance is contained in a first fluid and a second substance in an additional introduced fluid.

23. Use of the method and/or the static micromixer as claimed in one or more of the preceding claims for producing a gas/liquid dispersion, wherein at least one introduced fluid contains a gas or a gas mixture and at least one additional introduced fluid contains a liquid, a liquid mixture, a solution, a dispersion or an emulsion.
